(19) United States
(12) Patent Application Publication
(10) Pub. No.: US 2009/0032906 A1
(43) Pub. Date: Feb. 5, 2009

(54) ELECTRO STATIC DISCHARGE DEVICE AND METHOD FOR MANUFACTURING AN ELECTRO STATIC DISCHARGE DEVICE

(75) Inventors: Thomas Ostermann, Koestenberg (AT); Nicola Vannucci, Fuernitz (AT)

Correspondence Address: DICKSTEIN SHAPIRO LLP, 1177 AVENUE OF THE AMERICAS 6TH AVENUE, NEW YORK, NY, 10036-2714, US

(73) Assignee: Infineon Technologies Austria AG, Villach (AT)

(21) Appl. No.: 11/830,532

(22) Filed: Jul. 30, 2007

(51) Int. Cl. H01L 27/06; H01L 21/8222

(52) U.S. Cl. 257/539; 438/330; 257/E27.021; 257/E21.608

(57) ABSTRACT

An electro static discharge device includes a semiconductor body. The semiconductor body includes a first surface, a first semiconductor region of a first conductivity type, a second semiconductor region of a second conductivity type arranged on the first semiconductor region and a third semiconductor region of the first conductivity type. The third semiconductor region is isolated from the first semiconductor region by the second semiconductor region. A resistor structure is arranged in the semiconductor body and comprises at least one trench structure. The resistor structure is arranged at least in the second semiconductor region and provides a high-resistance electrical connection between a first portion and a second portion of the second semiconductor region.

### BACKGROUND OF THE INVENTION

The increasing use of delicate semiconductor devices and integrated circuits in demanding environments, such as automotive applications, requires appropriate protective devices such as Electro Static Discharge (ESD) devices. Integrated circuits (IC) employed in harsh conditions need a robust protection at different operating conditions.

Effective ESD devices should be able to support ESD-HBM (Human Body Model) and ESD-MM (Machine Model) stresses which relates to different surge voltages. Such protective structures must also withstand at least a minimum current during an ESD-pulse and provide reliable protection throughout the whole system lifetime.

Some ESD devices typically comprise a polysilicon resistor having a pre-defined resistance and a dedicated diode. Other ESD devices comprise field-effect transistors. Such ESD devices, however, lack flexibility with respect to the covered voltage range. This is particularly important when considering different types of ICs and different applications which require different minimum protection voltages and currents. Further, many ESD protective structures assume a large area of the chip area which leads to increased costs.

### BRIEF SUMMARY OF THE INVENTION

According to an embodiment, an electro static discharge device is provided which comprises a semiconductor body. The semiconductor body comprises a first surface, a first semiconductor region of a first conductivity type, a second semiconductor region of a second conductivity type, which is arranged on the first semiconductor region, and a third semiconductor region of the first conductivity type. The third semiconductor region is isolated from the first semiconductor region by the second semiconductor region. A resistor structure is arranged in the semiconductor body and comprises at least one trench structure. The resistor structure is arranged at least in the second semiconductor region and provides a high-resistance electrical connection between a first portion and a second portion of the second semiconductor region.

The resistor structure arranged at least in the second semiconductor region allows a flexible adjustment of its resistance by appropriately arranging and designing the trench structure. The design of the trench structure can be selected according to specific needs and applications. By appropriately defining the resistance of the resistor structure, the protection voltage of the ESD structure can be controlled.

### BRIEF DESCRIPTION OF THE DRAWINGS

These and other advantages including a full and enabling disclosure of the present invention, including the best mode thereof, to one of ordinary skill in the art, is set forth more particularly in the remainder of the specification, including reference to the accompanying figures. Therein:

FIG. 1 shows a circuit diagram of an ESD structure according to an embodiment.

FIG. 2 illustrates the variation of the breakdown voltage BV_{CE} in dependence on the resistance of the resistor structure.

FIG. 3 shows a cross-sectional view of an ESD device according to an embodiment.

FIG. 4 shows a plan view of the metallization layout of the ESD device of FIG. 3.

FIG. 5 shows another plan view of the metallization layout of the ESD device of FIG. 3.

FIGS. 6A and 6B show a plan view and a cross-sectional view of the arrangement of doping regions of the embodiment shown in FIG. 3.

FIGS. 7 and 8 show the layout of the trench structure of the embodiment shown in FIG. 3.

FIG. 9 shows a cross-sectional view of an ESD device according to another embodiment.

FIG. 10 shows the layout of the trench structure of the embodiment shown in FIG. 9.

FIG. 11 shows the metallization layout of the embodiment shown in FIG. 9.

FIG. 12 shows a circuit diagram of the ESD structure shown in FIG. 9.

FIG. 13A shows a layout of a trench structure according to another embodiment.

FIG. 13B shows a layout of a trench structure according to another embodiment.

FIG. 14 shows a layout of a trench structure according to another embodiment.

### DETAILED DESCRIPTION OF THE INVENTION

Reference will now be made in detail to various embodiments, one or more examples of which are illustrated in the figures. Each example is provided by way of explanation, and is not meant as a limitation of the invention. For example, features illustrated or described as part of one embodiment can be used on or in conjunction with other embodiments to yield yet a further embodiment. It is intended that the present invention includes such modifications and variations. The examples are described using specific language which should not be construed as limiting the scope of the appending claims. The drawings are not scaled and are for illustrative purposes only.

The term “lateral” as used in this specification intends to describe an orientation parallel to the main surface of a semiconductor body such as wafer or die.

The term “vertical” as used in this specification intends to describe an orientation which is arranged perpendicular to the main surface of the semiconductor semiconductor body such as wafer or die.

Specific embodiments described in this specification pertain to ESD devices and particularly to ESD devices comprising a vertical bipolar transistor. Specifically, the ESD device comprises a vertical large area junction bipolar transistor comprising and internal base and/or collector resistance formed by a resistor structure having an appropriately designed “trench labyrinth”. The invention, however, is not limited thereto.

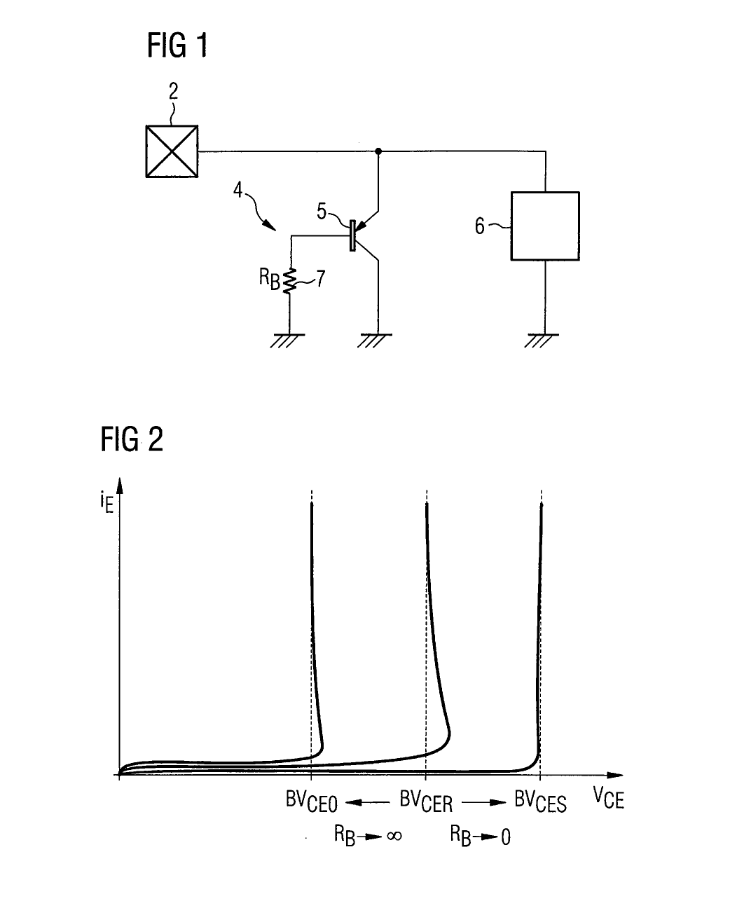

FIG. 1 shows a circuit diagram of an ESD device 4 according to a first embodiment. The ESD device 4 comprises a bipolar transistor 5 and a resistor denoted by 7. The collector of the bipolar transistor 5 is directly connected with ground. The base of the bipolar transistor 5 is connected to ground through resistor 7. The emitter of the bipolar transistor is connected with a pad structure 2 of an IC 6. ESD device 4 protects IC 6 from high electro static voltages between the pad structure 2 and ground.

By selecting the resistance R_{B} of resistor 7, the minimum protection voltage of the ESD device 4 can be defined. The dependence of the minimum protection voltage, which corresponds to the breakdown voltage BV_{CE} between collector and emitter, is schematically illustrated in FIG. 2. When R_{B} is small, the breakdown voltage BV_{CE} reaches its saturation value at BV_{CES}. On the other hand, when R_{B} increase, the breakdown voltage decrease to eventually reach BV_{CE0}. The variation of the breakdown voltage can be significant and for many application, a high resistance R_{B} is desired to lower the breakdown voltage BV_{CE}. This is particularly relevant for delicate electronic devises which cannot even withstand low voltage surges.

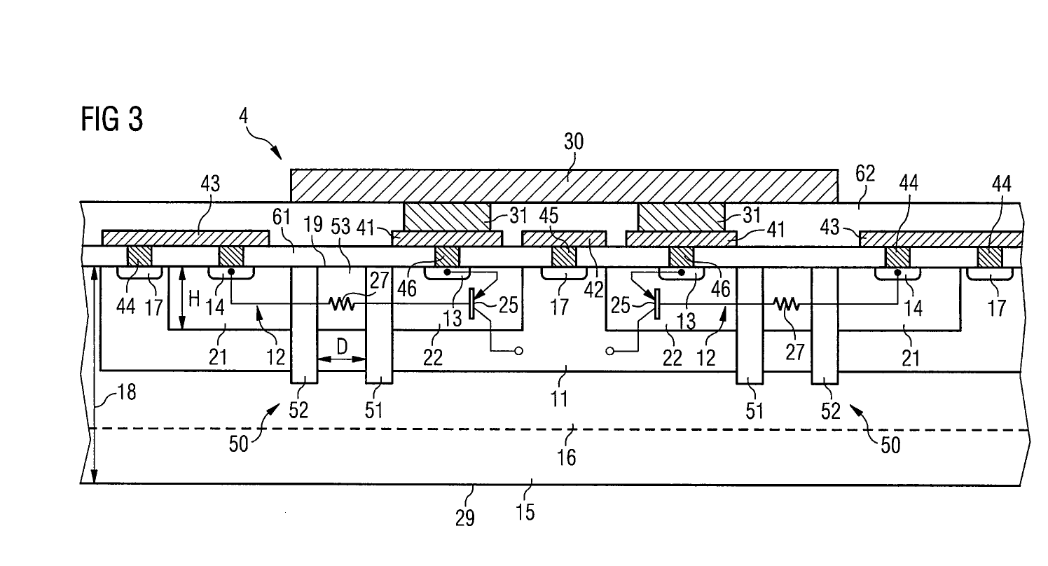

FIG. 3 shows a cross-sectional view of an electro static discharge device 4 according to a first embodiment which comprises a semiconductor body 18. The semiconductor body 18 can be comprising of any suitable semiconductor material such as silicon (Si), silicon carbide (SiC) or a junction semiconductor such as gallium arsenide (GaAs). The semiconductor body, the vertical extension of which is indicated by arrow 18, comprises a first surface 19. This surface forms a main surface of the semiconductor body 18. Typically, the semiconductor body 18 is n-doped. Semiconductor body 18 comprises a second surface 29 which is arranged opposite to the first surface 19.

In this embodiment, the semiconductor body 18 is formed by a semiconductor substrate 15 and an epitaxial layer 16 formed on the semiconductor substrate 15. The upper surface of the epitaxial layer 16 forms the first surface 19 of the semiconductor body 18. The semiconductor substrate 15 can be for instance highly n-doped. A skilled person will appreciate that the semiconductor body 18 can also be a single crystal material without an epitaxial layer.

A p-doped first semiconductor region 11 is arranged in the semiconductor body 18, particularly in the epitaxial layer 16. First semiconductor region 11 can be formed as a buried layer or, as in this embodiment, as a p-well and is used as p-isolation well and as collector.

An n-doped second semiconductor region 12 is arranged in the epitaxial layer 16 on the first semiconductor region 11. In this embodiment, second semiconductor region 12 is formed as an n-well embedded in the first semiconductor region 11 at the first surface 19 of the semiconductor body 18. The second semiconductor region 12 has a typical doping concentration from about 5*10¹⁵/cm³ to about 1*10¹⁶/cm³ and forms here a base region.

A p-doped third semiconductor region 13 is arranged on the second semiconductor region 12 such that it is isolated from and spaced to the first semiconductor region 11 by the second semiconductor region 12. The third semiconductor region 13 is arranged at the first surface 19 of the semiconductor body 18 and forms here an emitter region.

In certain embodiments, p-doped regions are of a first conductivity type while n-doped regions are of a second conductivity type. Those skilled in the art will appreciate that first and second conductivity type can also be reversed. The first, second and third semiconductor regions 11, 12, 13 form here together a vertical pnp bipolar transistor having large area junctions as described later.

A resistor structure 50 comprising at least one trench structure 51, 52 is arranged at least in the second semiconductor region 12. In this embodiment, two trench segments are shown which form an inner ring structure 51 and an outer ring structure 52 as will become more apparent from the description below. Typically, the ring structures 51, 52 extend, in the cross-section perpendicular to the first surface 11, from the first surface 19 through the second semiconductor region 12 at least to the first semiconductor region 11. The ring structures 51, 52 divide the second semiconductor region 12 in a first portion 21 and a second portion 22 such that a high-resistance electrical connection is provided between the first portion 21 and the second portion 22 of the second semiconductor region 12.

In this embodiment, the ring structures 51, 52 extend from the first surface completely through the second and the first semiconductor region 11, 12 to thereby separating the first and second semiconductor regions 11, 12 in respective first and second portions. Extending through the first semiconductor region 11 is, however, not required as becomes apparent from the description below since the ring structures 51, 52 are mainly for defining a resistor 27 in the second semiconductor region 12.

The third semiconductor region 13 is arranged in the second portion 22 of the second semiconductor region 12 at the first surface 19 of the semiconductor body 18.

A highly n-doped fourth semiconductor region 14 is arranged in the first portion 21 of the second semiconductor region 12 and forms here a base contact region.

The electrical connection between the first and the second portion 21, 22 of the second semiconductor region 12 is provided by a conductive portion 53 of the second semiconductor region 12 having a reduced cross-sectional area in comparison with the first and second portions 21, 22. The cross-sectional area of the conductive portion 53 is defined or limited by the ring structures 51, 52. Particularly, the ring structures 51, 52 restrict the cross-sectional area in lateral direction while the cross-sectional area in vertical direction is bounded by thickness H of the second semiconductor region 12, which thickness H is defined by the distance between the first semiconductor region 11 and the first surface 19. The distance D between adjacent trench structures 51, 52 is selected such that the cross-sectional of the conductive portion 53 is made small to increase its resistance. The cross-sectional area is defined here in a cross-section perpendicular to the first surface 19.

The length L of the conductive portion 53 is defined by the layout and arrangement of the trench structure in a projection onto the first surface 19. For illustrating this, reference is made to FIG. 13A showing an embodiment of the trench structure in a plan view on the first surface 19. A circularly arranged trench structure 50 comprises a non-continuous inner ring structure 51 and a non-continuous outer ring structure 52 surrounding the inner ring structure 51. Each ring structure 51, 52 is formed by respective two trench segments 51-1, 51-2 and 52-1, 52-2, respectively, which form together a respective circular structure. The trench segments 51-1, 51-2 and 52-1, 52-2 are of semi circular arc shape. Gaps 51-3, 52-3 are arranged between the trench segments 51-1, 51-2 and 52-1, 52-2 of the respective trench structures 51, 52. The inner ring structure 51 is rotated by 90° with respect to the outer ring structure 52 about its rotational axis so that the gaps 51-3, 52-3 are displaced by 90° to each other.

In this description, the term “non-continuous” intends to describes that the ring structures or trench structure do not form a closed structure but are discontiguous or “broken” due to the gaps formed therein. The trench structure or the ring structure comprises at least one gap for providing the electrical connection between the first and the second portions.

The radial distance between the inner and the outer ring structures 51, 52 corresponds here to the distance D as indicated in FIG. 3. The cross-sectional area A of the conductive portion 53 extending between the inner and the outer ring structure 51, 52 is defined by D*H. The length L of the conductive portion 53 corresponds in this embodiment to a quarter of the circumference of a circle. Electrical current from the second portion 22 of the first semiconductor region 12, which is surrounded by the trench structure 50, to the first portion 21 of the semiconductor portion outside of the trench structure 50 flows through a gap 51-3 of the inner ring structure 51, the conductive portion 53 and a gap 52-3 of the outer ring structure 52.

Given a specific resistance p of the material of the second semiconductor region 12, resistance R of each conductive portion 53 is given by R=ρ*L/A=ρ*L/(D*H). The resistance R of the conductive portion 53 can therefore be adjusted by suitably scaling the geometrical proportions. In the embodiment given above, the electrical connection between the first portion 21 and the second portion 22 of the second semiconductor region 12 is provided by four conductive portions 53 each having a shape of a quarter circular arc. Hence, the total resistance of the electrical connection is

Rₜₒₜₐₗ=1/4*ρ*L/(D*H)

since the four conductive portions 53 a connected parallel to each other. By using appropriate geometrical shapes, the cross-sectional area of the conductive portion 53 can be reduced and its length extended to obtain any high-resistance connections. The influence of the gaps is not considered here for the sake of simplicity. A skilled person will appreciate that changing the size of the gaps will also add to the resistance.

The specific resistance p of the second semiconductor region 12 is mainly defined by its doping concentration. Since, a given doping concentration is typically desired in the second portion 22 (which functions as intrinsic base) of the second semiconductor region 12, the resistance of the conductive portion or portions 53 are mainly varied by changing the geometric circumstances. Typically, the distance D and the length L are changed to adjust the resistance. It is, however, also possible to change the doping concentration in the area of the conductive portions 53 for instance by selective implantation. Further, the thickness H of the second semiconductor region 12 can also be changed.

An example for further increasing the resistance by geometrical means is shown in FIG. 13B. Each of the inner and outer ring structure 51, 52 is formed by a single non-continuous ring segment 51-1, 52-2, each of which comprises only one gap 51-3, 52-3. The gaps 51-3, 52-3 are rotated with respect to each other by 180° so that two conductive portions 53 of semi circular arc shape are formed. Given that the specific resistance is ρ and that D and H are the same as in FIG. 13A and that L1=2*L, the total resistance Rₜₒₜₐₗ is given by

Rₜₒₜₐₗ=1/2*ρ*2*L/(D*H)=ρ*L/(D*H).

Hence, the total resistance Rₜₒₜₐₗ of the resistor structure 50 defined by the trench structure of FIG. 13B is four times higher than the resistance of the resistor structure defined by the trench structure of FIG. 13A.

Typically the total resistance Rₜₒₜₐₗ, which is the resistance R_{B} of the resistor 7 in FIG. 1, is in the range from about 1*10³ Ohm to about 1*10⁴ Ohm. Those skilled in the art will recognise that even higher values can be obtained by increasing the number of the ring structures and reducing the distance D between adjacent ring-structures. For example, a resistor structure with four concentrically arranged ring segments defining a meander-like shaped conductor portion 53 is shown in FIG. 14.

The trench structure 50 therefore defines a boundary of the conductive portion 53 or portions which form the high-resistance electrical connection between the first portion 21 and the second portion 22 of the second semiconductor region 22. To obtain a high resistance, the trench structure 50 comprises at least two spaced trench segments or ring structures, as for instance described above, which runs, in projection onto the first surface 19, at least in sections parallel to or along each other, wherein the conductive portion 53 is arranged between, and defined by, the trench segments.

The trench segments can be staggered with respect to each other. In case of the embodiments shown in FIGS. 13A and 13B staggering means that the ring-like trench segments are rotated with respect to each other. When the trench structure is formed by other geometrical structures such as long strait trench walls or stepped trench walls, staggering or displacing of the respective segments to each other is used to increase the length of the conductive portion 53 arranged between the trench segments.

The trench segments are typically comprised of an insulating material so that they are non-conductive. For manufacturing, trench segments according to a given or pre-selected layout are formed at least in the second semiconductor region 12 and, if desired, also in the first semiconductor region 11. Typically, the trench segments spans vertically completely through the second semiconductor region 12 and at least partially into the first semiconductor region 11. If the trench segments are also desired in the first semiconductor region 11, they also extend therethrough. Subsequently, the trench segments are filled with an insulating material such silicon oxide.

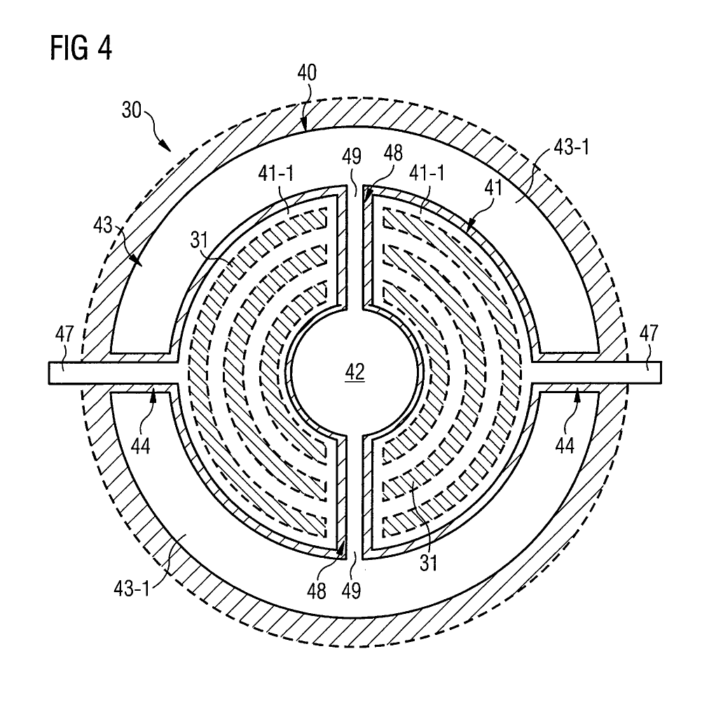

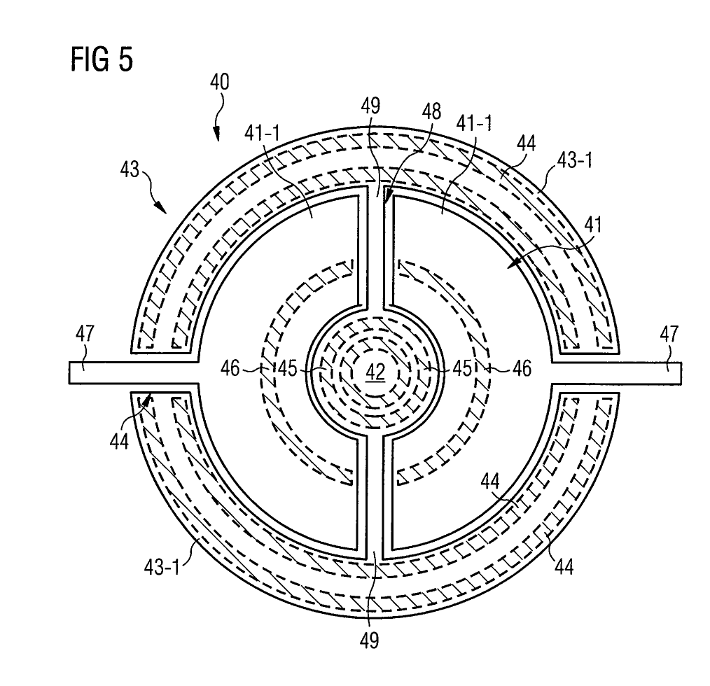

Turning back to FIG. 3, a first insulating layer 61 covers the first surface 11. A metallization structure 40 is arranged on the first insulating layer 61. Metallization structure 40 comprises an emitter contact portion 41, a collector contact portion 42 and a base contact portion 43. The layout of the metallization structure 40 will become apparent from FIGS. 4 and 5.

FIG. 4 shows a plan view (projection onto the first surface 19) of the metallization structure 40. The metallization structure 40 is in this embodiment substantially circular. Collector contact portion 42 is circular in shape and arranged centrally in the metallization structure 40. Emitter contact portion 41 comprises here two collector contact segments 41-1 which surround collector contact portion 42. The collector contact segments 41-1 can be shaped like semi circular arcs. Emitter contact portion 41 and collector contact portion 42 are laterally spaced to be electrically insulated from each other. A gap 48 is provided between the emitter contact segments 41-1 to provide space for a collector connection 49 between collector contact portion 42 and the base contact portion 43 which surrounds the emitter contact portion 41. Base contact portion 43 comprises two base contact segments 43-1 between which gaps 44 are provided to allow an emitter connection 47 to passing therethrough.

Turning back to FIG. 3, collector contact portion 42 is arranged above a highly p-doped central contact region 17 which is arranged in the first semiconductor region 11 at the first surface 19 of the semiconductor body 18. Highly p-doped peripheral contact regions 17 to the first semiconductor region 11 are arranged in outer regions of the ESD device 4. Central contact region 17 is connected with the collector contact portion 42 by a contact 45 formed in the first insulating layer 61. The arrangement of the contact 45 come more apparent from FIG. 5 which shows two concentric contact rings which form in this embodiment contact 45.

Emitter contact portion 41 is arranged above the third semiconductor region 13 and partially covers the resistor structure 50 when seen in a projection onto the first surface 19. A contact 46 is arranged in the first insulating layer 61 to provide an electrical connection between the third semiconductor region 13 and the emitter contact portion 41. Contact 46 is formed here by two semi circle arc-shaped contact segments each of which is in contact with a respective emitter contact segment 41-1.

Base contact portion 43 is arranged above the fourth semiconductor region 14 and the peripheral contact region 17 as illustrated in FIG. 3 and contacted to each of these regions by contacts 44 which run along the circular extension of the respective base contact segments 43-1. Base contact portion 43 provides through peripheral contact regions 17 also an electrical connection to the first semiconductor region 11. Since first semiconductor region 11 forms the collector and the second semiconductor region forms the base of the vertical bipolar transistor both are connected with each other and with ground.

Different thereto, the emitter of the bipolar transistor formed by the third semiconductor region 13 is connected through contact 46, emitter contact portion 41, and vias 31 with a pad metallization 30 arranged above metallization structure 40. Metallization structure 40 is arranged between the first surface 19 of the semiconductor body 18 and the pad metallization 30 and is insulated from pad metallization 30 by a second insulating layer 62. The pad metallization 30 covers, in projection onto the first surface 19, the complete ESD device 4 and forms here, for example, a pad contact such as an input pad of an IC.

As it becomes apparent from the above description, the inherent resistance of the second semiconductor region 12 is increased by the trench structure which reduces the available cross-sectional area of the second semiconductor region 12 in a region between its first and second portion 22 and thereby defines the shape and cross-sectional area of the conductive portion 53 of the second semiconductor region 12 arranged between its first and the second portion 21, 22.

The ESD device as described herein has, in the cross-section perpendicular to the first surface 18, a substantially symmetrical arrangement with respect to an axis arranged perpendicular to the first surface 18. In a plan view, the ESD device 4 is substantially circularly arranged.

An advantage of such a structure is that the ESD device can be integrated under the pad metallization 30 and does not assume further space in the semiconductor body 18. This provides for a more compact arrangement, smaller chip area and short electrical connections which is of high advantage for protective devices.

Another advantage is correlated with the structure of the vertical bipolar transistor. The bipolar transistor comprises flat and big junctions which assume a great area. The bipolar transistor is therefore capable to providing a low-resistance electrical connection between the pad metallization 30 and ground in case that an ESD pulse occurs.

The ESD device further exhibit high performance in term of robustness and charge dissipation capability (thermal dissipation capability), since the discharge current flows through the vertical bipolar transistor having flat and large junctions.

Moreover, the vertical arrangement of the bipolar transistor guarantees a good stability of its electrical characteristics.

In addition to that the protection voltage of the ESD device can be flexibly defined by varying the layout of the trench structure.

The ESD device as described herein is particularly suitably for integrated circuits and devices which have a drain contact on the second surface of the semiconductor body.

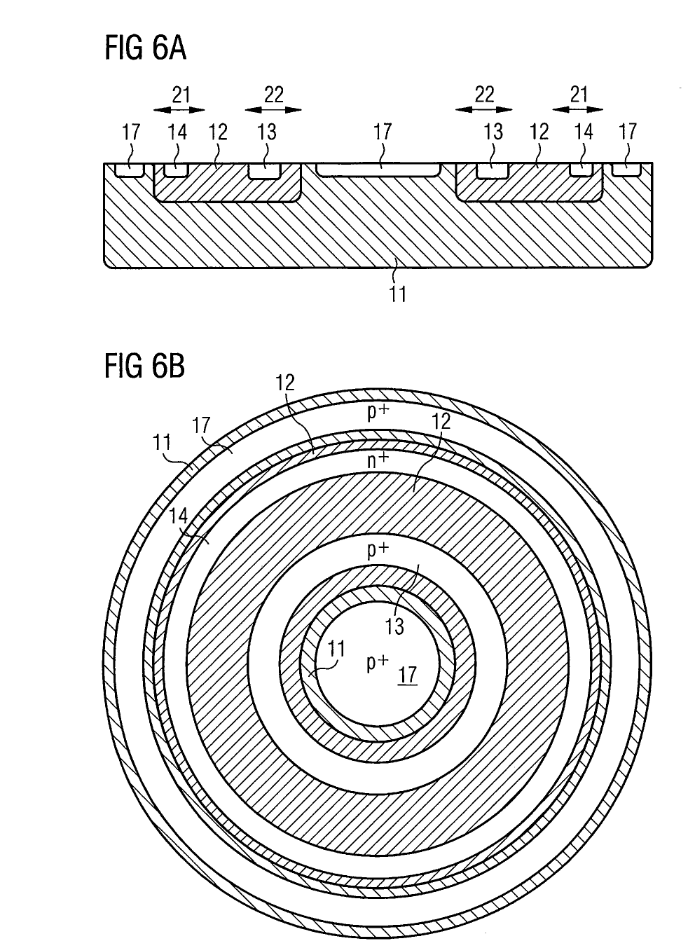

The arrangement of the junctions of the bipolar transistor will become more apparent from FIGS. 6A, 6B, 7 and 8 which shows a plan view of the first surface 18. In these Figures, the semiconductor substrate 15 is not shown.

First semiconductor region 11 is formed here as a large p-well and can extend to other regions in the semiconductor body 18 which are not shown. The first semiconductor region can be formed by implantation and may serve as isolation well to isolate second semiconductor region 12 from n-doped regions of the semiconductor body 18.

Second semiconductor region 12, which is ring-liked formed, is embedded into the first semiconductor region 11. This arrangement provides for a large pn-junction between the first and the second semiconductor region 11, 12. The second semiconductor region 12 can be formed by implantation to form an n-well, which is completely surrounded at its periphery and its lower border by the first semiconductor region 11.

The highly p-doped third semiconductor region 13 is ring-like shaped and embedded in the second portion 21 of the second semiconductor region 12. The third semiconductor region 13 can be for instance formed together with the central and peripheral contact regions 17, all of which are highly p-doped. Peripheral contact region 17 is ring-liked shaped and laterally surrounds the second semiconductor region 12, whereas the central contact region 17 has a compact circular shape. Contact regions 17 provides electrical connection to the first semiconductor region 11 and thus to the collector of the bipolar transistor.

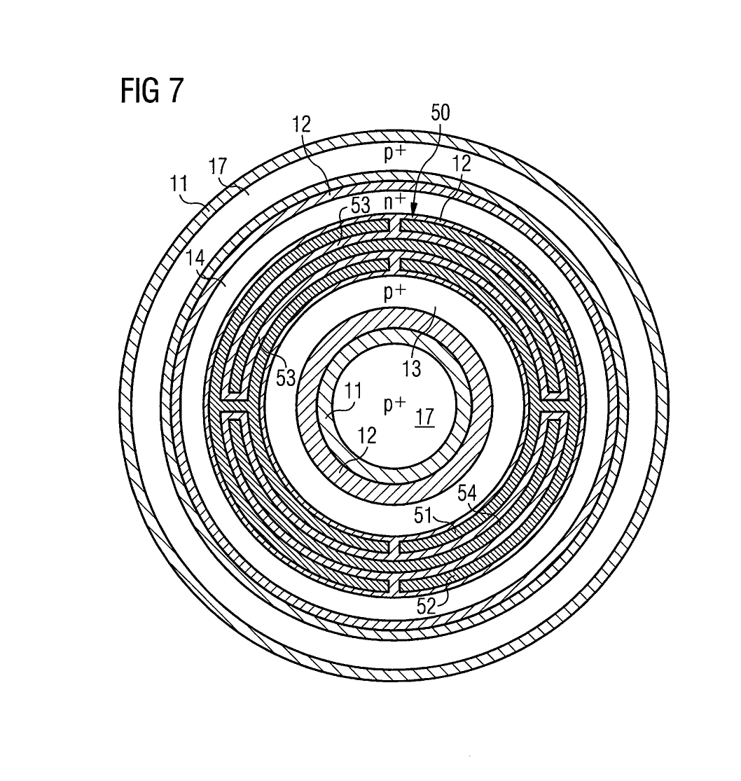

For contacting the second semiconductor region 12, the fourth semiconductor region 14 is also ring-like shaped to surround the third semiconductor region 13 although sufficient space is allowed for between them to arrange the trench structure as illustrated in FIG. 7.

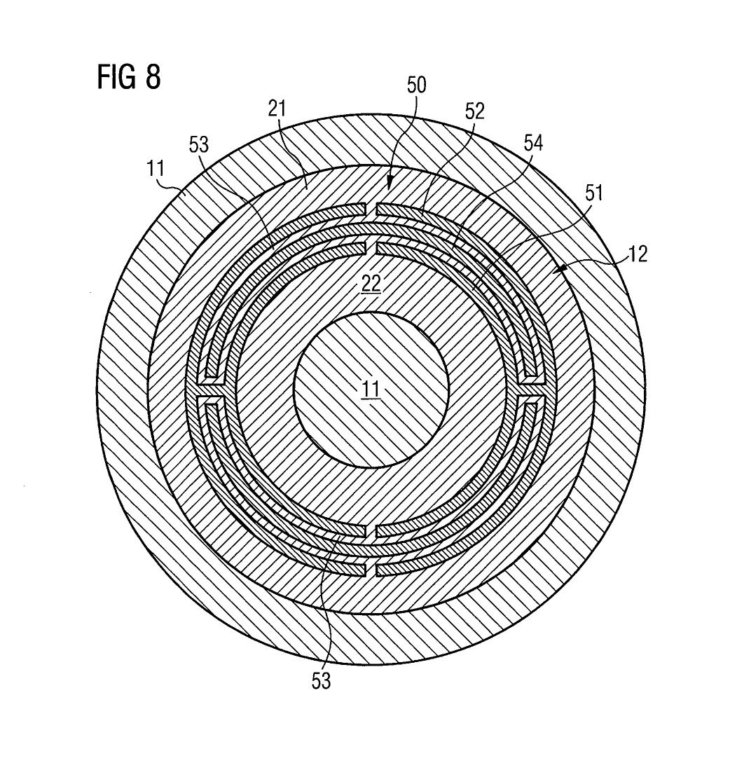

The resistor structure 50 shown in FIGS. 7 and 8 comprises three concentrically arranged trench structures 51, 52 and 54 between which the conductive portion 53 is arranged which provides the electrical connection between the first (outer) portion 21 of the second semiconductor region 12 and the second (inner) portion 22 of the second semiconductor region 12.

FIG. 8 shows the resistor structure 50 embedded in the second semiconductor region 12 without showing the third, fourth and the contact region regions 13, 14 and 17, respectively. As it becomes apparent form FIG. 8 the second portion 22 of the semiconductor region 12 is surrounded, in a projection onto the first surface 18, by the first portion 21 of the second semiconductor region with the trench structures 51, 52, 54 being arranged between the first and the second portions 21, 22.

The vertical bipolar transistor has therefore a circular or ring-like arrangement and comprises concentrically arranged semiconductor regions, forming the base and the emitter region embedded in a collector well.

Other ESD devices comprise a field-effect transistor. High voltages between source and drain of the field-effect transistor trigger the inherent parasitic bipolar transistor of the field-effect which then provides an electrical connection to ground. Different thereto, the present ESD device comprises a real vertical bipolar transistor and not a parasitic structure of a field-effect transistor. This allows the formation of large area junctions contrary to parasitic bipolar transistors which often have only small area junctions and in which the source and drain of the field-effect transistor which form emitter and collector of the bipolar transistor are significantly spaced to each other which restrict the current flow.

The onset voltage of the present bipolar transistor is crucial for the effectiveness of the ESD device. If desired, a plurality of bipolar transistors stacked in a cascade configuration can be used to cover a broad range of critical voltages.

For forming the ESD device 4 the semiconductor body 18 is provided comprising the first, second and third semiconductor region 11, 12, 13, respectively. These regions are typically formed by implantation in this order to arrange same on top of each other or in a stacked-manner. In addition to that, the fourth semiconductor region 14 and the contact regions 17 can be formed by implantation.

In a further step, the resistor structure 50 is formed as indicated above by, for example, etching trenches in the semiconductor body 18, which are subsequently filled with an insulating material. After forming the resistor structure 50, the first insulating layer 61 is deposited and structured to provide openings to the respective semiconductor regions. The openings are filled with a conductive material to form the contacts to the subsequently formed metallization structure 40, which is deposited onto the first insulating layer 61. The metallization structure 40 is structured, typically by etching.

This arrangement is then covered by the second insulating layer 62 in which openings are formed to provide an electrical connection to the emitter contact portion 41 of the metallization structure 40. The openings are then filled with a conductive material to form vias 31 which connects the emitter contact portion 41 of the metallization structure 40 with the pad metallization 30 formed on the second insulating layer 62.

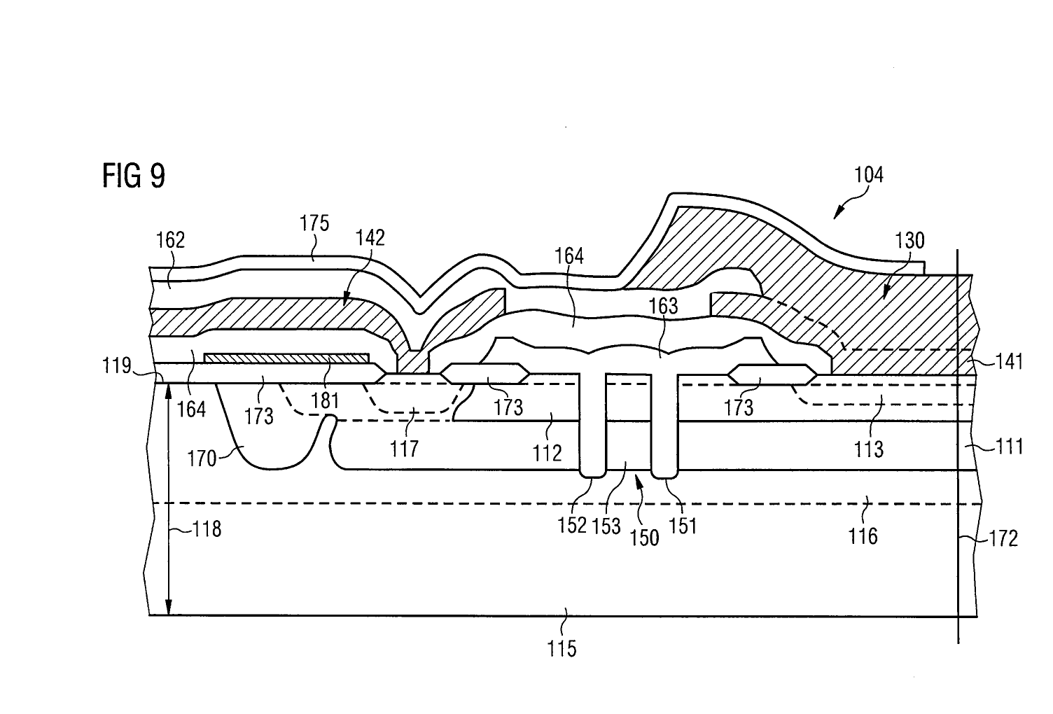

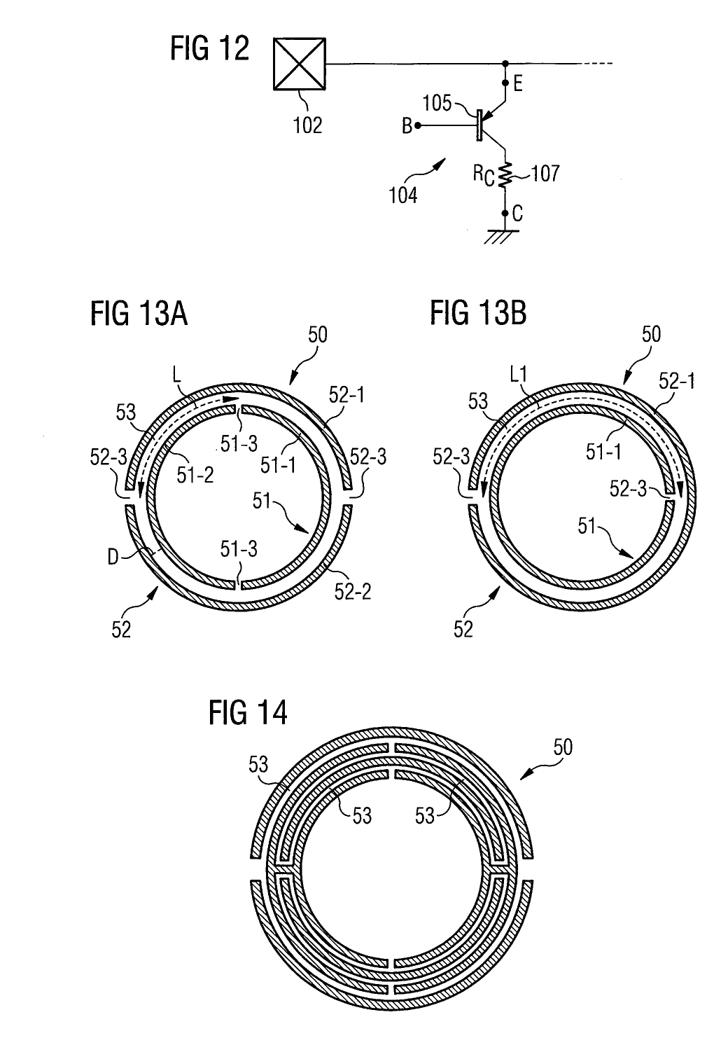

Another embodiment of an ESD device 104 is shown in FIGS. 9 to 11. The corresponding electrical diagram is shown in FIG. 12. In this embodiment, the resistor 107 is arranged between the collector of the bipolar transistor 105 and ground. Base is floating, while the emitter is connected with a pad structure 102.

FIG. 9 shows a cross-section perpendicular to a first surface 119 of a semiconductor body 118, which is comprised of a highly n-doped semiconductor substrate 115 and a n-doped epitaxial layer 116. In the epitaxial layer 116, a p-doped first semiconductor region 111 (isolation well, collector) is formed. On the p-well 111, and in contact therewith, a n-doped second semiconductor region 112 (base) is arranged which is laterally isolated from the n-region of the epitaxial layer 116 by a peripheral p-well 170 and a p-doped contact region 117 which is in contact with the first semiconductor region 111.

A p-doped third semiconductor region 113 (emitter) is embedded in the second semiconductor region 112 and separated or isolated from the first semiconductor region 111 by the second semiconductor region 112. Similar to the first embodiment, the first, second and third semiconductor regions 111, 112 and 113 form together a vertical bipolar transistor having large flat junctions.

Field oxide portions 173 are formed on the first surface 119 to separate peripheral contact region 117 from the second semiconductor region 112 and the second semiconductor region 112 from the third semiconductor region 113, respectively. In a peripheral region of the ESD device 104, a polysilicon layer 181 used as a local electrical connection for devices not shown here can be arranged on the field oxide 173.

A resistor structure 150 extends through the second semiconductor region 112 and completely through the first semiconductor region 111 to define a first portion 121 and a second portion 122 of the first semiconductor region 111. The resistor structure 150 can comprise a first and a second trench structure 151, 152 which are spaced from each other to define a conductive portion 153 therebetween. The trench structures 151, 152 can be of similar shape as in the first embodiment.

The trench structures 151, 152 are filled with a conductive material 163 such as TEOS. The resistor structure 150 and the second semiconductor region 112 are covered by a BPSG layer 164 which provides insulation against a first metallization layer comprising an emitter contact portion 141 and a collector contact portion 142, each of which being in contact with the third semiconductor region 113 and the peripheral contact region 117, respectively. The area of the first semiconductor region 111 which contributes to the series resistance enhanced by the resistor structure 150 is indicated in FIG. 9 by dotted lines.

A second insulating layer 162, for instance formed by IMD, covers the collector contact portion 142 and the BPSG layer 164 but leaves the emitter contact portion 141 uncovered so that this portion is in contact with a contact pad 130. A passivation layer 175 covers the complete structure except the pad contact 130 to provide for an external connection to the contact pad 130. By defining the resistance within the first semiconductor region 111 between the peripheral contact region 117 and the second portion 122 the breakdown voltage of the bipolar transistor can be adjusted.

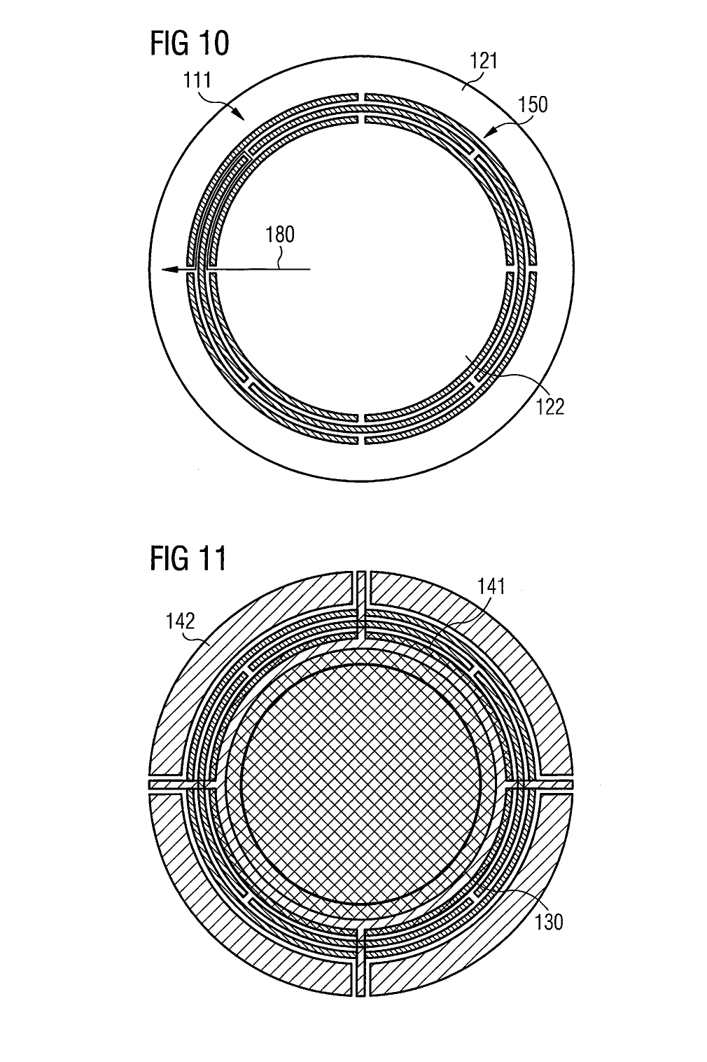

The structure shown in FIG. 9 is rotationally symmetrical with respect to a vertical axis 172 similar to the first embodiment. The circular arrangement of this embodiment is shown in FIGS. 10 and 11.

First portion 121 of the first semiconductor region 111 (collector) is separated from the inner second portion 122 by the trench structure 150 which comprises a trench structure similar to the one described in the first embodiment. The geometrical path of the current from the second to the first portion 22, 21 through the resistor structure 150 is denoted by 180.

Collector contact portion 142, segmented into four quarter regions, surrounds the central emitter contact portion 141. As FIG. 11 shows, the contact pad 130 is arranged above the emitter contact region 141.

As illustrated above, the trench structure of the resistor structure typically forms a trench labyrinth to provide a narrow and long conductive portion of reduced cross-sectional area which forms a high-resistance connection between the inner (second) and outer (first) portion of the first (collector) and/or the second (base) semiconductor region. The resistor structure is, however, not restricted to the above shown configurations and can be modified to be of any shape such as meander-like or spiral.

The written description above uses specific embodiments to disclose the invention, including the best mode, and also to enable any person skilled in the art to make and use the invention. While the invention has been described in terms of various specific embodiments, those skilled in the art will recognise that the invention can be practiced with modification within the spirit and scope of the claims. Especially, mutually non-exclusive features of the embodiments described above may be combined with each other. The patentable scope is defined by the claims, and may include other examples that occur to those skilled in the art. Such other examples are intended to be within the scope of the claims if they have structural elements that do not differ from the literal language of the claims, or if they include equivalent structural elements with insubstantial differences from the literal languages of the claims.

What is claimed is:

1. An electro static discharge device, comprising:
a semiconductor body comprising a first surface, a first semiconductor region of a first conductivity type, a second semiconductor region of a second conductivity type arranged on the first semiconductor region, and a third semiconductor region of the first conductivity type which is isolated from the first semiconductor region by the second semiconductor region; and
a resistor structure comprising at least one trench structure, the resistor structure being arranged at least in the second semiconductor region and providing a high-resistance electrical connection between a first portion and a second portion of the second semiconductor region.

2. The electro static discharge device of claim 1, wherein the at least one trench structure extends, in a cross-section perpendicular to the first surface, from the first surface through the second semiconductor region at least to the first semiconductor region.

3. The electro static discharge device of claim 1, wherein the third semiconductor region is arranged in the second portion of the second semiconductor region.

4. The electro static discharge device of claim 1, further comprising a fourth semiconductor region of the second conductivity type arranged in the first portion of the second semiconductor region.

5. The electro static discharge device of claim 1, wherein the trench structure extends, in the cross-section perpendicular to the first surface, from the first surface completely through the second and the first semiconductor region to thereby separating the first and second semiconductor regions into respective first and second portions.

6. The electro static discharge device of claim 1, wherein the trench structure defines a boundary of a conductive portion which forms the high-resistance electrical connection between the first portion and the second portion of the second semiconductor region.

7. The electro static discharge device of claim 6, wherein the trench structure comprises at least two spaced non-conductive trench segments which run, in projection onto the first surface, at least in sections along each other, wherein the conductive portion is arranged between the trench segments.

8. The electro static discharge device of claim 1, wherein the second portion of the semiconductor region is surrounded, in a projection onto the first surface, by the first portion of the second semiconductor region with the trench structure being arranged between and separating the first and the second portions.

9. The electro static discharge device of claim 8, wherein the trench structure comprises, in a projection onto the first surface, non-conductive spaced trench segments forming a non-continuous ring-shaped structure which surrounds the first portion of the second semiconductor region, the trench segments defining a boundary of a conductive portion which forms the high-resistance electrical connection between the first portion and the second portion of the second semiconductor region.

10. The electro static discharge device of claim 9, wherein the trench segments form at least an outer and an inner ring structure such that the conductive portion runs, at least in sections, between and along the outer and the inner ring structure.

11. The electro static discharge device of claim 9, wherein the trench segments forming at least three non-continuous concentric ring structures which surrounds the second portion of the second semiconductor region such that the conductive portion runs through the trench structure in a meander-like manner.

12. The electro static discharge device of claim 1, further comprising a pad metallization in connection with the third semiconductor region.

13. The electro static discharge device of claim 12, further comprising a metallization structure for electrically connecting the first semiconductor region with the second portion of the second semiconductor region, wherein the metallization structure is arranged between the first surface of the semiconductor body and the pad metallization.

14. An electro static discharge device, comprising:
a semiconductor body having a first surface;
at least a semiconductor region arranged in the semiconductor body, the semiconductor region comprising a first and a second portion, wherein, in a projection onto the first surface, the second portion is surrounded by the first portion; and
a trench structure surrounding, in the projection onto the first surface, the second portion and separating the first portion from the second portion, the trench structure defining a high resistance conductive portion for electrically connecting the first portion with the second portion.

15. The electro static discharge device of claim 14, wherein the trench structure comprises a ring-like shape.

16. The electro static discharge device of claim 14, wherein the trench structure comprises, in projection onto the first surface, non-conductive trench segments forming a ring-shaped non-continuous structure, the trench segments forming a boundary of the conductive portion.

17. The electro static discharge device of claim 16, wherein the non-conductive trench segments form at least an outer and an inner non-continuous ring structure such that the conductive portion of high conductivity runs, at least in sections, between and along the outer and the inner ring structures.

18. An electro static discharge device, comprising:
a semiconductor body comprising a first surface, a first semiconductor region of a first conductivity type, a second semiconductor region of a second conductivity type arranged on the first semiconductor region, and a third semiconductor region of the first conductivity type which is isolated from the first semiconductor region by the second semiconductor region;
the second semiconductor region comprising a first and a second portion, wherein, in a projection onto the first surface, the second portion is surrounded by the first portion; and
a resistor structure comprising non-conductive trench segments and at least one high-resistance conductive portion for electrically connecting the first portion with the second portion, the trench segments forming at least an inner and an outer non-continuous trench structure wherein the conductive portion runs, at least in sections, along and between the inner and outer trench structures.

19. The electro static discharge device of claim 18, further comprising a pad metallization in contact with the third semiconductor region, wherein the first, second and third semiconductor regions are arranged, in a cross-section perpendicular to the first surface, substantially under the pad metallization.

20. A method for manufacturing an electro static discharge device, comprising:
providing a semiconductor body;
forming a first semiconductor region of a first conductivity type in the semiconductor body;
forming a second semiconductor region of a second conductivity type on the first semiconductor portion;
forming a third semiconductor region of the first conductivity type which is isolated from the first semiconductor region by the second semiconductor region; and
forming a resistor structure comprising at least one trench structure, the resistor structure being arranged at least in the second semiconductor region and providing a high-resistance electrical connection between a first portion and a second portion of the second semiconductor region.

21. The method of claim 20, wherein the step of forming the resistor structure comprises forming at least two spaced-apart non-conductive trench segments at least in the second semiconductor region such that a conductive portion of the second semiconductor region remains for forming the electrical connection between the first and the second portion.

22. The method of claim 20, wherein the step of forming the resistor structure comprises forming spaced-apart non-conductive trench segments at least in the second semiconductor region, the trench segments forming portions of a ring-like trench structure comprising at least an inner and an outer ring structure such that a conductive portion of the second semiconductor region for forming the electrical connection between the first and the second portion is arranged between the inner ring and the outer ring structure.

23. The method of claim 20, wherein the resistor structure is formed such that the resistor structure is arranged between the first portion of the second semiconductor region and the second portion of the second semiconductor region.

24. The method of claim 20, wherein the semiconductor body comprises a first surface, and wherein the resistor structure is formed such that, in a projection onto the first surface, the resistor structure surrounds the second portion of the second semiconductor region.

25. The method of claim 20, further comprising forming a metallization structure on the semiconductor body for electrically connecting the first portion of the second semiconductor region with the first semiconductor region.

26. The method of claim 20, further comprising forming a pad metallization structure on the semiconductor body in contact with the third semiconductor region.

27. An electro static discharge device, comprising:
a semiconductor body comprising a first surface, a first semiconductor region of a first conductivity type, a second semiconductor region of a second conductivity type arranged on the first semiconductor region, and a third semiconductor region of the first conductivity type which is isolated from the first semiconductor region by the second semiconductor region; and
a resistor means, which comprises at least one trench structure and is arranged at least in the second semiconductor region, for providing a high-resistance electrical connection between a first portion and a second portion of the second semiconductor region.
